(19) United States
(12) Patent Application Publication
(10) Pub. No.: US 2024/0429305 A1
(43) Pub. Date: Dec. 26, 2024

(54) Semiconductor Device Having FIN Structure and Method of Forming Thereof

(71) Applicant: Taiwan Semiconductor Manufacturing Company, Ltd., Hsinchu (TW)

(72) Inventors: Chia-Min YU, Hsinchu City (TW); Chii-Horng LI, Hsinchu County (TW); Hsueh-Chang SUNG, Hsinchu County (TW)

(21) Appl. No.: 18/470,614

(22) Filed: Sep. 20, 2023

Related U.S. Application Data
(60) Provisional application No. 63/509,665, filed on Jun. 22, 2023.

(51) Int. Cl. H01L 29/66; H01L 21/02; H01L 21/306; H01L 21/308; H01L 29/06; H01L 29/423; H01L 29/775

(52) U.S. Cl. CPC H01L 29/66439; H01L 21/02532; H01L 21/0262; H01L 21/30604; H01L 21/308; H01L 29/0673; H01L 29/42392; H01L 29/775

(57) ABSTRACT

Methods of forming and a semiconductor devices where the channel region includes a germanium-comprising layer; and a crystalline silicon layer on the germanium-comprising layer. A gate structure over a first surface and a second surface, the second surface opposing the first surface. In some implementations, the crystalline silicon layer can mitigate damage during processing.

This application is a non-provisional application of and claims benefit of U.S. Provisional Patent Application Ser. No. 63/509,665 filed Jun. 22, 2023, the entire disclosure of which is incorporated herein by reference.

### BACKGROUND

Multigate devices have been introduced to improve gate control and can increase gate-channel coupling, reduce off-state current, reduce short-channel effects (SCEs), or a combination thereof. One such device is a fin-type field effect transistor (FinFET), having a semiconductor fin extending from a substrate, with a gate interfacing one or more surfaces of the fin. Another such multigate device is a gate-all around (GAA) device, which includes a gate structure that extends, partially or fully, around a channel region to provide access to the channel region on at least two sides. As multi-gate devices enable aggressive scaling down of integrated circuit (IC) technologies, maintaining gate control and mitigating short channel effects, while seamlessly integrating with conventional IC manufacturing processes raise challenges. Accordingly, although existing multi-gate devices and methods for fabricating such have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a semiconductor structure, according to one or more aspects of the present disclosure.

FIGS. 2A and 2B are cross-sectional views of an embodiment of a semiconductor structure, FIG. 2C is a corresponding perspective view, according to one or more aspects of the present disclosure.

FIGS. 3A-3M, 3O are cross-sectional views of an embodiment of forming a semiconductor structure comprising a semiconductor fin, according to one or more aspects of the present disclosure. FIG. 3N is a corresponding perspective view.

FIG. 4A is a cross-sectional view of another embodiment of a semiconductor structure, and FIG. 4B is a corresponding perspective view, according to one or more aspects of the present disclosure.

FIG. 5 is a cross-sectional view of another embodiment of a semiconductor structure, according to one or more aspects of the present disclosure.

FIGS. 6, 7, 8, 9, 10, 11A, 11B, 11C, 11D, 11E, 12, and 13A are cross-sectional views of embodiments of semiconductor structures for fabrication of a multigate device, and FIG. 13B is a corresponding cross-sectional view along an active region (perpendicular to a gate), according to aspects of the present disclosure. FIG. 14 is a corresponding perspective view.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper.” “horizontal,” “vertical,” “above,” “over,” “below,” “beneath,” “up,” “down,” “top.” “bottom,” etc. as well as derivatives thereof (e.g., “horizontally,” “downwardly.” “upwardly.” etc.) are used for ease of the present disclosure of one features relationship to another feature. The spatially relative terms are intended to cover different orientations of the device including the features. Furthermore, when a number or a range of numbers is described with “about,” “approximate.” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

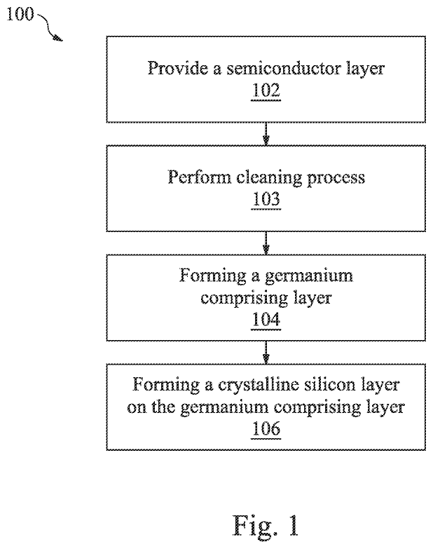

FIG. 1 is a flow chart of a method 100 for fabricating a semiconductor structure, in portion or entirety, according to various aspects of the present disclosure. At block 102, a semiconductor layer is provided. The semiconductor layer may be a first semiconductor material composition. In some implementations, the first semiconductor material is silicon. In some implementations, the first semiconductor material is silicon germanium. Other semiconductor material compositions such as, for example, compound semiconductors, such as silicon carbide, gallium arsenide, gallium phosphide, indium phosphide, indium arsenide, indium antimonide; an alloy semiconductor, such as SiGe, GaAsP, AlInAs, AlGaAs, GaInAs, GaInP, GaInAsP, and/or other suitable semiconductor materials are also within the scope of the disclosure. The first semiconductor layer may be a substrate (e.g., wafer) or a layer formed on a substrate. The first semiconductor layer may be a semiconductor structure providing a channel of a transistor such as a semiconductor structure of a fin designed to provide a channel region for a fin-type field effect transistor, or a nanostructure designed to provide a channel region for a gate all around device.

In some implementations at block 103, in some embodiments, a cleaning process may be performed on the semiconductor layer. In some embodiments of the method 100, block 103 is omitted. The cleaning process may provide an oxidate removal on the semiconductor layer. The cleaning process may include a dry etching process, a wet etching process, a plasma based process and/or other suitable processes. In some implementations, the process temperature is between approximately 0° C. and approximately 160° C. In an embodiment, the cleaning process is performed using a precursor (or etchant) of fluorine (F₂), hydrogen fluoride (HF), chlorine (Cl₂), hydrogen chloride (HCl), ammonia (NH₃), nitrogen trifluoride (NF₃), ammonium fluoride (NH₄F) and/or other precursors. In some implementations, the process (and precursors) are provided with a plasma activation. In some implementations, the process (and precursors) are provided without plasma activation. In an embodiment, the precursor is NH₃ without plasma. In an embodiment, the precursor is HF without plasma. The cleaning process may be performed at a pressure of between approximately 0.1 Torr and approximately 5.0 Torr.

At block 104, a germanium-comprising composition is formed on the semiconductor layer of block 102. In an embodiment, the germanium-comprising composition is formed directly on the first semiconductor material of the semiconductor layer. In an embodiment, the germanium-comprising layer is deposited on the first semiconductor material of silicon or including silicon. In an embodiment, germanium is deposited by atomic layer deposition (ALD), CVD, physical vapor deposition (PVD), high density plasma CVD (HDPCVD), MOCVD, RPCVD, PECVD, LPCVD, atomic layer CVD (ALCVD), atmospheric pressure CVD (APCVD), sub-atmospheric CVD (SACVD), other suitable methods, or a combination thereof. In an embodiment, the germanium-comprising layer is formed by diffusion. For example, when performing the deposition of block 106, germanium from a surrounding layer may diffuse towards the crystalline silicon of block 106. Thus, a germanium-comprising layer results. In some implementations, a thickness of the germanium comprising layer is between approximately 0.1 and approximately 20 nm. In an embodiment, the germanium-comprising composition consists of depositing germanium (e.g., only germanium). In an embodiment, the germanium-comprising composition includes depositing silicon germanium layer. In some implementations, the semiconductor layer of block 102 includes germanium and as such, block 104 is omitted.

The method 100 continues to block 106 where a crystalline silicon layer (c-Si) is provided on the germanium comprising layer. In an embodiment, the crystalline silicon layer is a monocrystalline silicon layer. In the crystalline silicon layer, a tetrahedral structure of silicon atoms continues over a large range, forming a well-ordered crystal lattice. In an embodiment crystalline silicon is homogeneous throughout the layer; the orientation, lattice parameter, and electronic properties are constant throughout the material. In an embodiment, the crystalline silicon layer may be formed by any suitable deposition process such as chemical vapor deposition (CVD), atomic layer deposition (ALD), epitaxial process, and/or other suitable deposition processes. In an embodiment, a deposition process may be performed at a temperature of between approximately 200° C. to approximately 1000° C. In an embodiment, a deposition process may be performed at a pressure between approximately 0.1 Torr to approximately 5 Torr. In an embodiment, a precursor is provided in the deposition process. The precursors may be selected from silane (SiH₄), disilane (Si₂H₆), trisilane (Si₃H₈), high-order Silane (SiₙH₂ₙ₊₂, n>3), and/or other suitable precursor. In an embodiment, the precursor is SiH₄. In an embodiment, the precursor is Si₂H₆. The precursor, which provides a silicon source, may be provided with an inert carrier gas.

Additional processing of the method 100 is contemplated by the present disclosure. Additional steps can be provided before, during, and after method 100, and some of the steps described can be moved, replaced, or eliminated for additional embodiments of method 100. The discussion that follows illustrates various embodiments of multigate-based integrated circuit devices that can be fabricated according to method 100. The following figures each illustrate implementations of the method 100, or portions thereof. Including as illustrated below, in some implementations of the method 100, the structure formed is used to form a channel region of a semiconductor device. The semiconductor device may be a multigate device such as a fin-type field effect transistor, a gate all around device including a complementary field effect transistor.

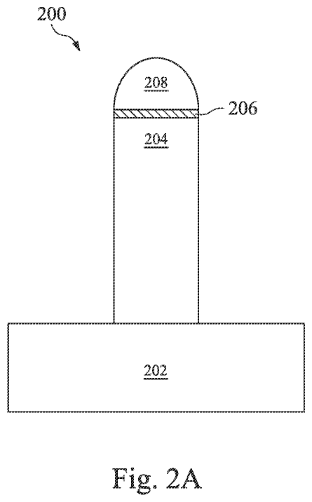

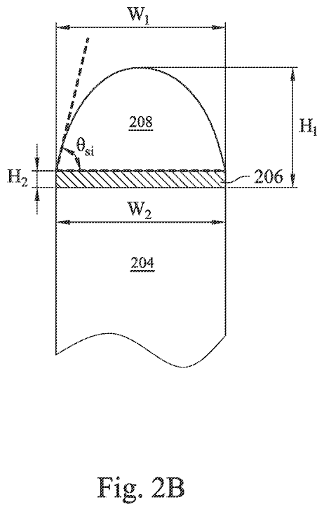

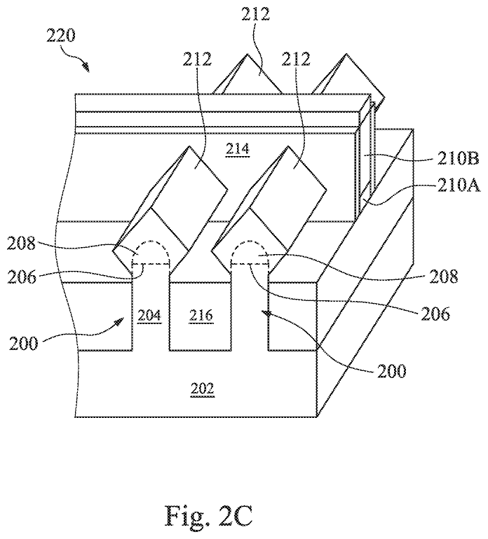

Referring to the example of FIG. 2A, illustrated is a semiconductor structure 200. The semiconductor structure 200 may be fabricating according to aspects of the method 100, described above with reference to FIG. 1. The semiconductor structure 200 includes a substrate 202. A fin 204 extends from the substrate 202. The fin 204 may comprise a first semiconductor material. The fin 204 includes an upper surface of the first semiconductor material. In an embodiment, the upper surface may be substantially planar and parallel a top surface of the substrate 202. In an embodiment, the fin 204 comprises a same semiconductor material (e.g., silicon) as the substrate 202. In an embodiment, the fin 204 is silicon. In another embodiment, the fin 204 is silicon germanium. The fin 204 may be formed according to aspects of block 102 of the method 100 of FIG. 1, discussed above.

In an embodiment, substrate 202 includes silicon. Substrate 202 may alternatively or additionally include another elementary semiconductor, such as germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In some embodiments, substrate 202 is a semiconductor-on-insulator substrate, such as a silicon-on-insulator substrate, a silicon germanium-on-insulator substrate, or a germanium-on-insulator substrate. In some implementations, fabrication of fins 204 may include performing a lithography and/or etching process to pattern the substrate 202. In some implementations, the fabrication of fins 204 may include growing an epitaxial semiconductor layer on the substrate 202 and etching the grown layer (alone or in combination with the substrate 202) to form the fins 204.

A layer 206 is disposed on the fin 204. In an embodiment, the layer 206 is a second semiconductor composition. In some implementations, the layer 206 is a different composition than the fin 204. In an embodiment, the layer 206 comprises germanium. In an embodiment, the layer 206 is germanium (e.g., substantially pure germanium). In an embodiment, the layer 206 is silicon germanium (SiGe). The layer 206 may include a substantially uniform thickness. The layer 206 may be formed according to aspects of block 104 of the method 100 of FIG. 1, discussed above. In some implementations, the layer 206 is a germanium-comprising layer deposited over the fin 204 (e.g., silicon). In some implementations, the layer 206 is a germanium-comprising layer formed by diffusion of germanium to the layer 206 during the formation of the upper portion 208.

An upper portion 208 is disposed over the layer 206. In an embodiment, the upper portion 208 comprises a crystalline silicon (c-Si) material. The upper portion 208 may be formed according to aspects of block 106 of the method 100 of FIG. 1, discussed above. The upper portion 208 is a different composition than the layer 206. For example, a c-Si material of the upper portion 208 is formed on the germanium-comprising composition of the layer 206. In an embodiment, the upper portion 208 includes a same atomic composition as the fin 204. For example, in some implementations, the upper portion 208 and the fin 204 are silicon. As illustrated in FIG. 2A, the upper portion 208 may completely cover the upper surface of the layer 206. The upper portion 208 may have a rounded or curvilinear upper surface extending from the layer 206 on a first sidewall to the layer 206 on a second sidewall.

FIG. 2B illustrates an inset of FIG. 2A having a plurality of exemplary dimensions noted. In an embodiment, the layer 206 has a width W2 and a height H2. In an embodiment, width W2 is between approximately 0.1 nanometers (nm) and approximately 20 nm. In an embodiment, the height H2 is between approximately 0.1 and approximately 5.0 nm. In an embodiment, the upper portion 208 has a height H1 and a width at a bottom surface of W1. In an embodiment, width W1 is between approximately 0.1 nanometers (nm) and approximately 20 nm. In an embodiment, the height H1 is between approximately 0.1 and approximately 10.0 nm. In an embodiment, the upper portion 208 has a curved upper surface. An angle θ1 is an angle of silicon extending above the layer 206. The angle θ1 is between approximately 0<0≤approximately 1200.

In an embodiment, the structure 200 provides for an active region of a transistor device such as a fin-type field effect transistor (FinFET). In an embodiment, the structure 200 provides a channel region of FinFET. In particular, the upper portion 208 (e.g., c-Si) may include at least a portion of a channel region. And in an embodiment, the fin 204 (e.g., Si) includes at least a portion of a channel region. FIG. 2C is illustrative of a perspective view of the structure 200 as a portion of the device 220. The device 220 is a FinFET. A gate structure 210 is disposed over the structure 200, and source/drain regions 212 are disposed on each side of the gate structure 210 to form the FinFET 220. The gate structure 210 includes a gate dielectric layer 210A and an overlying gate electrode layer 210B. Spacer elements 214 abut the sidewalls of the gate structure 210. Isolation features 216 interpose the fins 204. The gate structure 210 engages the upper portion 208, the layer 206, and the fin 204.

The isolation regions 216 may be shallow trench isolation (STI) features. Alternatively, a field oxide, a LOCOS feature, and/or other suitable isolation features may be implemented on and/or within the substrate 202. The isolation regions 216 may be composed of silicon oxide, silicon nitride, silicon oxynitride, fluorine-doped silicate glass (FSG), a low-k dielectric, combinations thereof, and/or other suitable material known in the art. In an embodiment, the isolation regions 216 are STI features and are formed by etching trenches in the substrate 202. The trenches may then be filled with isolating material, followed by a chemical mechanical polishing (CMP) process. However, other embodiments are possible. In some embodiments, the isolation regions 216 may include a multi-layer structure, for example, having one or more liner layers.

The device 220 also include a source region 212 and a drain region 212 where the source/drain regions 212 are formed in, on, and/or surrounding the semiconductor structure 200. The source/drain regions 212 may be formed by recessing the structures 200, including etching the top portion 208, the germanium-comprising layer 206 and portions of the fin 204, to form a source/drain recess. An epitaxial material is then grown within the recess to form the source/drain regions 212. Epitaxial growth is achieved by a molecular beam epitaxy (MBE) process, a chemical vapor deposition (CVD) process, a metalorganic chemical vapor deposition (MOCVD) process, other suitable epitaxial growth process, or a combination thereof. Epitaxial source/drains 212 may be doped with n-type dopants and/or p-type dopants. In some embodiments (e.g., when forming portions of n-type transistors), epitaxial source/drains 212 include silicon that may be doped with carbon, phosphorous, arsenic, other n-type dopant, or a combination thereof (e.g., Si: C epitaxial source/drains, Si: P epitaxial source/drains, or Si: C: P epitaxial source/drains). In some embodiments (e.g., when forming portions of p-type transistors), epitaxial source/drains 212 include silicon germanium or germanium, which may be doped with boron, other p-type dopant, or a combination thereof (e.g., Si: Ge: B epitaxial source/drains). In some embodiments, epitaxial source/drains 212 include more than one epitaxial semiconductor layer, where the epitaxial semiconductor layers may include the same or different materials and/or the same or different dopant concentrations. In some embodiments, epitaxial source/drains 212 include materials and/or dopants that achieve desired tensile stress and/or compressive stress in channel regions of the semiconductor structure 200. In some embodiments, epitaxial source/drains 212 are doped during deposition by adding impurities to a source material of the epitaxy process (i.e., in-situ). In some embodiments, epitaxial source/drains 212 are doped by an ion implantation process after a deposition process.

The gate structure 210 includes a gate dielectric 210A and a gate electrode 210B disposed on the gate dielectric 210A. In some embodiments, the gate dielectric 210A may include an interfacial layer such as silicon oxide layer (SiO₂) or silicon oxynitride (SiON), where such interfacial layer may be formed by chemical oxidation, thermal oxidation, atomic layer deposition (ALD), chemical vapor deposition (CVD), and/or other suitable method. In some examples, the gate dielectric 210A includes a high-k dielectric layer such as hafnium oxide (HfO2). Alternatively, the high-k dielectric layer may include other high-k dielectrics, such as TiO2, HfZrO, Ta₂O₃, HfSiO4, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. High-K gate dielectrics, as used and described herein, include dielectric materials having a high dielectric constant, for example, greater than that of thermal silicon oxide (˜3.9). In still other embodiments, the gate dielectric 210A may include silicon dioxide or other suitable dielectric. The gate dielectric 210A may be formed by ALD, physical vapor deposition (PVD), CVD, oxidation, and/or other suitable methods. In some embodiments, the gate electrode 210B may be deposited as part of a gate first or gate last (e.g., replacement gate) process. In various embodiments, the gate electrode 210B includes a conductive layer such as W, Ti, TIN, TiAl, TiAlN, Ta, TaN, WN, Re, Ir, Ru, Mo, Al, Cu, Co, CoSi, Ni, NiSi, combinations thereof, and/or other suitable compositions. The gate electrode 210B may include work function metals tuned for the device performance. In some embodiments, the gate electrode 210B may alternately or additionally include a polysilicon layer. In various examples, the gate electrode 210B may be formed using PVD. CVD, electron beam (e-beam) evaporation, and/or other suitable process. The sidewall spacers 214 may include a dielectric material such as silicon oxide, silicon nitride, silicon carbide, silicon oxynitride, or combinations thereof.

It is noted that the structure 200 in the channel region, under the gate 210, may be configured substantially similar to as illustrated in FIGS. 2A and 2B. In some implementations, a gate dielectric layer, for example, an interfacial layer, may be formed directly on the structure 200 including directly on the surface of the upper portion 208 and/or the germanium-comprising layer 206 (if present).

In some implementations, during the fabrication of the FinFET 220 including forming the gate structure (replacement or metal gate) over the structure 200 may include introducing an oxygen source around the structure 200. An advantage of the structure 200 may be mitigation of oxidizing of the fin structure due to the crystalline silicon layer 208. Another advantage of the structure 200 may be mitigation of damage such as pitting to the fin structure 200 due to presence of the crystalline silicon layer 208. The crystalline silicon layer 208 may serve to protect the fin 204. For example, in some implementations, the fin structure 200 is annealed. The crystalline silicon layer 208 avoids being consumed during subsequent oxidation due to the oxidation rate of silicon in crystalline form compared to amorphous silicon

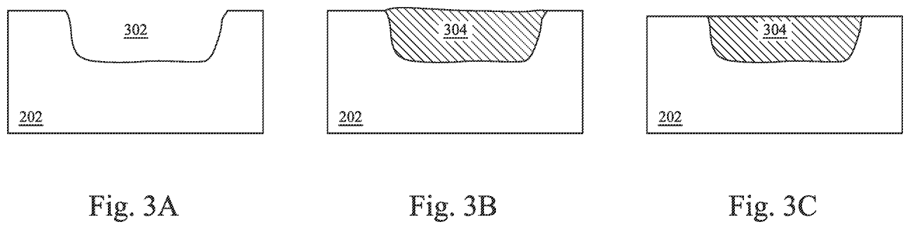

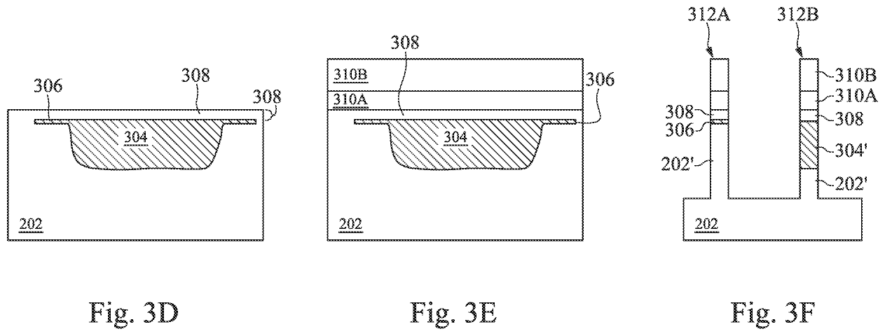

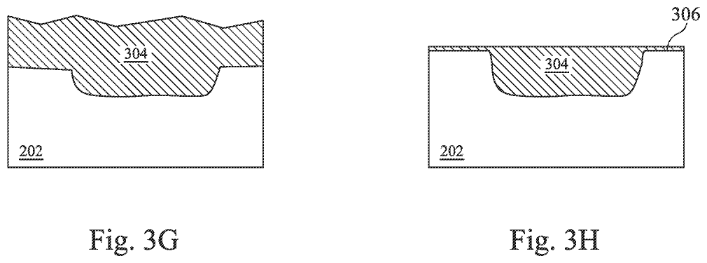

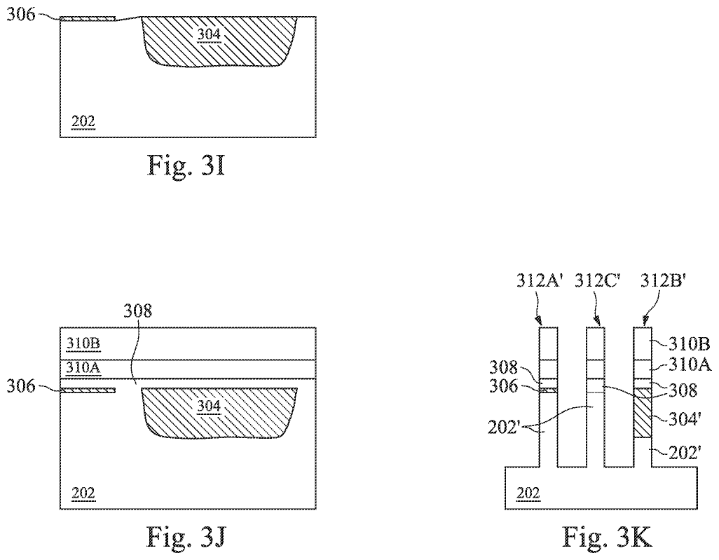

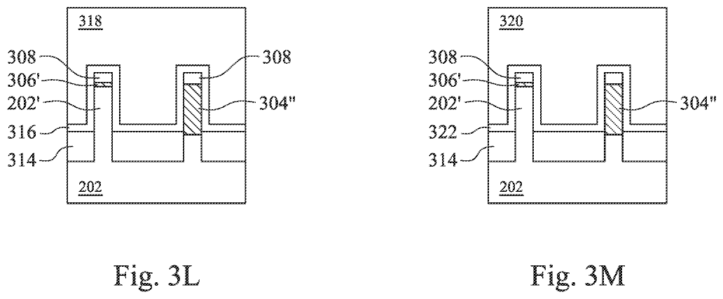

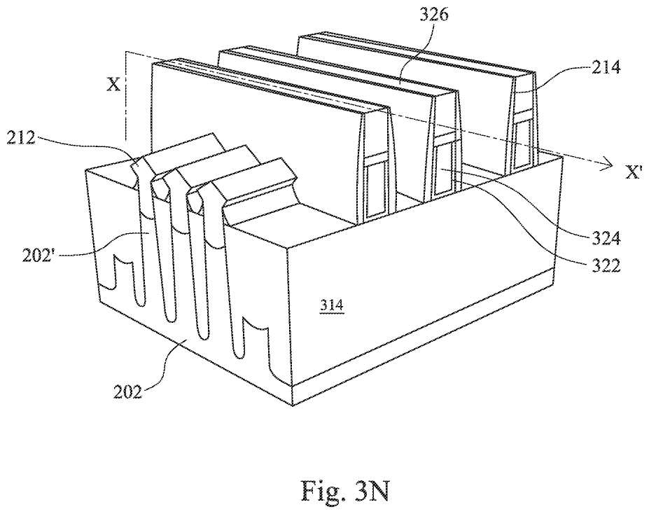

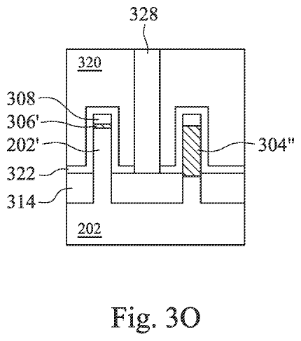

Referring now to FIGS. 3A-3O, illustrated are process steps in forming a transistor device such as a FinFET device. In an embodiment, the FinFET device may be formed according to aspects of the method 100 of FIG. 1. In an embodiment, the device 220 of FIGS. 2A, 2B, and 2C may be fabricated according to aspects of FIGS. 3A-3O. Referring to example of FIG. 3A, a substrate 202 is provided. In an embodiment, the substrate 202 may be a silicon substrate. In a further embodiment, the substrate 202 may be a bulk silicon substrate. The substrate 202 may be substantially similar to as discussed above.

A recess 302 is etched in the semiconductor substrate 202. The recess 302 may be formed by using a lithography process to pattern an opening in a masking layer (not shown) and performing an etching process on areas exposed by the openings in the masking element to remove portions of the substrate 202. The etching may be performed by wet and/or dry etching processes. The recess 302 may include areas of the substrate 202 within which active regions are to be formed. In an implementation, the recess 302 is formed to include areas of the substrate 202 within which active regions of a second semiconductor material (e.g., SiGe), different than that of the substrate 202 (e.g., Si), are to be formed. In an embodiment, providing the substrate 202 including the recess 302 may be performed such as discussed above with reference to the method 100 and block 102 discussed above with reference to FIG. 1.

A second semiconductor material 304 is grown in the recess 302, as illustrated in FIG. 3B. The second semiconductor material 304 may be formed by molecular beam epitaxy (MBE) process, a chemical vapor deposition (CVD) process, a metalorganic chemical vapor deposition (MOCVD) process, other suitable epitaxial growth process, or a combination thereof. The second semiconductor material 304 may be different than the semiconductor material of the substrate 202. In an embodiment, the semiconductor material 304 includes a germanium-comprising layer. In an implementation, the germanium comprising layer 304 is silicon germanium. In an embodiment, providing the semiconductor material 304 may be performed such as discussed above with reference to the method 100 and block 104 discussed above with reference to FIG. 1. In an embodiment, the germanium-comprising layer 304 is silicon germanium formed by epitaxial growth in the recess 302.

As illustrated in FIG. 3B, the germanium-comprising layer 304 may slightly overfill the recess 302. A subsequent planarization process such as a chemical mechanical polish (CMP) may provide a substantially flat surface as illustrated in FIG. 3C. On this surface, a crystalline-silicon layer may be formed as discussed above.

In an embodiment, as illustrated in FIG. 3G, the germanium-comprising layer 304 may substantially overfill the recess 302 and form forming germanium-comprising layer on a top surface of the substrate 202. After a subsequent planarization process such as CMP, a germanium-comprising layer may continue to be disposed over of the substrate 202 upper surface as illustrated in FIG. 3H as germanium-comprising layer 306, which the germanium-comprising layer 304 fills the recess 302 in FIG. 3H. The germanium comprising layer 304/306 of FIG. 3H may be substantially similar to the germanium comprising layer 206 discussed above. In an implementation, the germanium comprising layer 306 of FIG. 3H has a thickness between approximately 0.1 and 5 nanometers. The germanium comprising layer 306 may be subsequently patterned to remove the germanium comprising layer 306 from certain regions of the substrate 202. Sec, e.g., FIG. 3D, FIG. 3I.

In an embodiment, as illustrated for example in FIG. 3D, when depositing a crystalline silicon layer 308 (discussed below), the germanium comprising layer 306 is formed by diffusion of germanium from the layer 304 towards the c-Si. The germanium comprising layer 306 formed by diffusion may extend from the region 304.

In some implementations, the germanium-comprising layer 306 adjacent the filled recess 302 of semiconductor material 304 is formed by separate deposition, patterning and/or etch processes. FIG. 3D and FIG. 3I are illustrations of the germanium-comprising layer 306 disposed over the substrate 202 which may be formed separately or concurrently with the semiconductor material 304 in the recess 302. The germanium-comprising layer 306 may be deposited and patterned such that the germanium-comprising layer 306 is maintained at regions of the substrate 202 where an active region (e.g., a silicon active region) is to be formed.

In some implementations, the germanium-comprising layer 306 is silicon germanium. In some implementations, the germanium-comprising layer 306 is germanium. In an implementation, the germanium-comprising layer 306 of FIG. 3D and/or FIG. 3I has a thickness between approximately 0.1 and 5 nanometers. The germanium-comprising layer 306 may be formed substantially similarly to as discussed above with reference to block 104 of the method 100 discussed above with reference to FIG. 1.

As illustrated in the method 100, a crystalline silicon (c-Si) portion is formed. Referring to the example of FIG. 3D, a crystalline silicon layer 308 is formed. The crystalline silicon layer 308 may be formed across an entirety of the substrate 202 as a conformal layer. In an embodiment, the crystalline silicon layer 308 has a thickness between approximately 0.1 nm and approximately 10 nm. The crystalline silicon layer 308 may be formed substantially as discussed above with reference to block 106 of the method 100. In an embodiment, the crystalline silicon layer 308 is deposited after the formation of the germanium-comprising layer 306. In an embodiment, the germanium-comprising layer 306 is formed concurrently with the crystalline silicon layer 308 through diffusion of germanium during the deposition of the crystalline silicon layer 308.

In addition to the embodiment of FIG. 3D, the embodiment of FIG. 3J also illustrates a crystalline silicon layer 308 formed over the substrate 202 and the germanium comprising layer 306 and over the filled region 304 (e.g., silicon germanium). As discussed above, crystalline silicon layer 308 may be formed across an entirety of the substrate 202 as a conformal layer. In an embodiment, the crystalline silicon layer 308 has a thickness between approximately 0.1 nm and approximately 10 nm. The crystalline silicon layer 308 may be formed substantially as discussed above including with reference to block 106 of the method 100.

The fabrication may continue to process the structure to form active regions of a semiconductor device including transistor channels. Referring to the examples of FIG. 3E and FIG. 3J, hard mask layers 310 including a first masking layer 310A and a second masking layer 310B are formed over the substrate 202. In an embodiment, the first masking layer 310A is an oxide layer, such as silicon oxide. In an embodiment, the second masking layer 310B is a nitride layer, such as silicon nitride. The hard mask layers 310 may be deposited by CVD, PVD, ALD, other suitable deposition process, or a combination thereof. Suitable lithography and etching processes are used to pattern the hard mask layers 310 and/or the underlying layers as illustrated in FIGS. 3F and 3K respectively.

Referring to the example of FIG. 3F, which progresses from FIG. 3E, two fin structures 312A and 312B are formed extending from the substrate 202. The fin structures may be formed by suitable photolithography and etching processes. The lithography process may include forming a resist layer over the hard mask 310 (for example, by spin coating), performing a pre-exposure baking process, performing an exposure process using a mask, performing a post-exposure baking process, and performing a developing process. After development, the patterned resist layer includes a resist pattern that corresponds with the mask. The etching process removes portions of the semiconductor layer stack and/or substrate 202 using the patterned resist layer and patterned hard mask 310 as an etch mask. The etching process is a dry etch, a wet etch, other suitable etching process, or a combination thereof. In some embodiments, the etching process is a reactive ion etching (RIE) process. After etching, the patterned resist layer and/or the hard mask 310 may be removed, for example, by a resist stripping process or other suitable process. In some embodiments, fins 312 are formed by a multiple patterning process, such as a double patterning lithography (DPL) process (for example, a lithography-etch-lithography-etch (LELE) process, a self-aligned double patterning (SADP) process, a spacer-is-dielectric (SID) SADP process, other double patterning process, or a combination thereof), a triple patterning process (for example, a lithography-etch-lithography-etch-lithography-ctch (LELELE) process, a self-aligned triple patterning (SATP) process, other triple patterning process, or a combination thereof), other multiple patterning process (for example, a self-aligned quadruple patterning (SAQP) process), or a combination thereof.

After etching, the first fin structure 312A includes an etched portion of the substrate 202, illustrated as mesa 202′, the germanium-comprising layer 306, and the crystalline silicon layer 308. The second fin structure 312B includes an etched portion of the substrate 202, illustrated as mesa 202′, a fin portion of germanium comprising layer 304, illustrated as fin portion 304′, and the crystalline silicon layer 308. Thus, in an embodiment, the fin structure 312B includes a silicon portion (202′), a silicon germanium portion (304′), and a crystalline silicon portion (308). And in an embodiment, the fin structure 312A includes a silicon portion (202′), a germanium comprising portion (306, which can be Ge or SiGe), and a crystalline silicon portion (308).

Referring to the example of FIG. 3K, three fin structures 312A′, 312B′ and 312C′ are formed extending from the substrate 202. The etching of the fin structures may be substantially similar to as discussed above with reference to FIG. 3F. In an embodiment, the first fin structure 312A′ includes an etched portion of the substrate 202, illustrated as mesa 202′, the germanium-comprising layer 306, and the crystalline silicon layer 308. The second fin structure 312B′ may include an etched portion of the substrate 202, illustrated as mesa 202′, a fin portion of germanium comprising layer 304, illustrated as fin portion 304′, and the crystalline silicon layer 308. And the third fin structure 312C′ may include an etched portion of the substrate 202, illustrated as mesa 202′, and the crystalline silicon layer 308. Any number of each configuration of the fin structures 312′ may be formed on the substrate and arranged in any order. Thus, in an embodiment, the fin structure 312B′ includes a silicon portion (202′), a silicon germanium portion (304′), and a crystalline silicon portion (308). And in an embodiment, the fin structure 312A′ includes a silicon portion (202′), a germanium portion (306, comprising for example Ge or SiGe), and a crystalline silicon portion (308). And in an embodiment, the fin structure 312C′ is formed of silicon.

The fin structures of FIG. 3F, like those of FIG. 3K, may form channel regions of one or more transistor devices. The configuration of the fins of FIG. 3F, 312A and 312B, are illustrated in FIGS. 3L and 3M. However, the embodiment of FIG. 3K may be fabricated in a substantially similar manner. Referring to the example of FIG. 3L, isolation features 314 are formed between bottom regions of the fin structures 312. The isolation features 314 may be substantially similar to the isolation features 216, discussed above with reference to FIG. 2C.

A dummy gate structure or stack is formed over the fin structures 312 and the isolation features 314. The dummy gate stack includes a dummy gate dielectric 316 and a dummy gate electrode 318. Dummy gate stack 316/318 extends lengthwise in a direction that is different than (e.g., orthogonal to) the lengthwise direction of fins 312. For example, dummy gate stack 316/318 extends along the y-direction, having a length in the y-direction, a width in the x-direction, and a height in the z-direction. The dummy gate stack 316/318 is disposed on tops and sidewalls of fin structures 312, such that the dummy gate stack 316/318 interfaces each of the fin portions 202′. 306, 304′ and/or 308 according to their presence in the fin structure 312.

Dummy gate dielectric 316 includes a dielectric material, such as silicon oxide, a high-k dielectric material, other suitable dielectric material, or a combination thereof. For example, dummy gate dielectric 316 is an oxide layer. Dummy gate electrode 318 includes a suitable dummy gate material, such as polysilicon. In some embodiments, dummy gate stack includes other layers, such as a capping layer, an interface layer, a diffusion layer, a barrier layer, or a combination thereof. Dummy gate stack is formed by deposition processes, lithography processes, etching processes, other suitable processes, or a combination thereof. In some implementations, the fin portion 308 comprising a crystalline silicon layer benefits the fin 312 in mitigating its damage to thermal and/or oxidation processes due to its composition and crystalline orientation.

After forming the dummy gate stack 316/318, source/drain features 212 (FIG. 3N) may be formed on, in or around the fin structures 312 in the source/drain region of the fin structures 312. The source/drain features may be substantially similar to the source/drain features 212 discussed above with reference to FIG. 2C. In some implementations, portions of the fin structure 312 (e.g., crystalline silicon 308, germanium comprising layer 306 and portions of the underlying layers) may be removed to form a recess within which the source/drain features 212 are formed.

The processing may continue to form a replacement gate in the position of the dummy gate stack after the source/drain regions have been formed. The replacement gate may include a gate dielectric 322 and a metal gate electrode 324 as illustrated in FIG. 3M. The gate dielectric may be substantially similar to the gate dielectric 210A discussed above with reference to FIG. 2C. In some embodiments, the gate dielectric 322 may include an interfacial layer such as silicon oxide layer (SiO₂) or silicon oxynitride (SiON), where such interfacial layer may be formed by chemical oxidation, thermal oxidation, atomic layer deposition (ALD), chemical vapor deposition (CVD), and/or other suitable method. In some examples, the gate dielectric 322 includes a high-k dielectric layer such as hafnium oxide (HfO2). Alternatively, the high-k dielectric layer may include other high-k dielectrics, such as TiO₂, HfZrO, Ta₂O₃, HfSiO₄, ZrO₂, ZrSiO₂, LaO, AlO, ZrO, TiO. Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, Si₃N₄, oxynitrides (SiON), combinations thereof, or other suitable material. High-K gate dielectrics, as used and described herein, include dielectric materials having a high dielectric constant, for example, greater than that of thermal silicon oxide (˜3.9). The gate dielectric 322 may be formed by ALD, physical vapor deposition (PVD), CVD, oxidation, and/or other suitable methods. The gate electrode 324 may be substantially similar to the gate electrode 210B discussed above with reference to FIG. 2C. In various embodiments, the gate electrode 324 includes a conductive layer such as W, Ti, TIN, TiAl, TiAlN, Ta, TaN, WN, Re, Ir, Ru, Mo, Al, Cu, Co, CoSi, Ni, NiSi, combinations thereof, and/or other suitable compositions. The gate electrode 324 may include work function metals tuned for the device performance. In various examples, the gate electrode 324 may be formed using PVD. CVD, electron beam (e-beam) evaporation, and/or other suitable process.

For ease of understanding, a perspective view of the device is illustrated in FIG. 3N, which shows a cross-sectional cut x-x′, extending in an x-direction, which is a cut representative of the cross-sectional views of FIGS. 3A-3M. FIG. 3N illustrates an optional hard mask layer 326 disposed over the gate electrode 324. The hard mask layer 326 may include one or more layers of oxide and/or nitride, or other suitable compositions.

In some embodiments, a gate cut process is performed to separate a gate structure 322/324 isolating resulting isolated portions of the gate structure 322/324 over a first fin 312A and a second fin 312b respectively. A dielectric feature 328 as illustrated in FIG. 3O interposes the gate segments. The dielectric feature 328 includes dielectric material that includes silicon, oxygen, carbon, nitrogen, other suitable dielectric constituent, or a combination thereof. For example, dielectric feature 328 may include silicon nitride, silicon carbonitride, silicon oxycarbonitride, silicon oxycarbide, or a combination thereof.

Thus, the series of FIGS. 3A-3O provide for implementing aspects of the method 100 of FIG. 1 for forming a FinFET device having a plurality of fin-type channel regions over which a gate structure is formed. The fin-type active channel regions include a top portion of crystalline silicon, which may be formed on a silicon fin (e.g., fin 312C′) or on a germanium comprising layer of the fin (e.g., 312A′, 312B′, 312A, 312B).

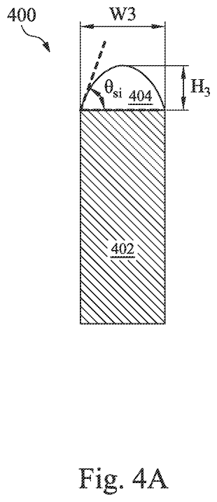

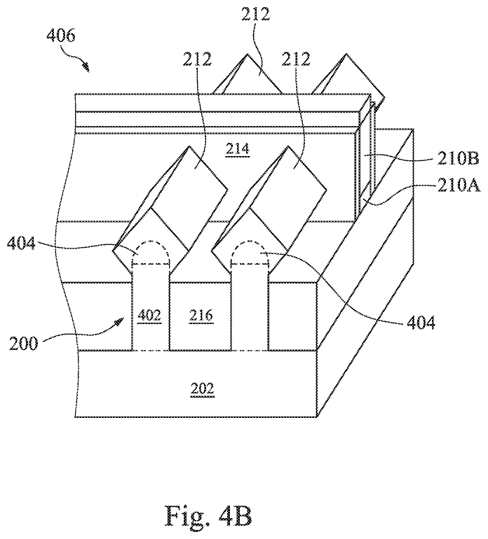

Referring to the example of FIG. 4A, illustrated is another semiconductor structure 400. In some implementations, the semiconductor structure 400 is formed on a substrate such as substrate 202 discussed above. In an embodiment, the semiconductor structure 400 is a fin type structure. In some implementations, the semiconductor structure 400 provides a channel region of a device such as a FinFET. The semiconductor structure 400 may be fabricated according to one or more aspects of the method 100, discussed above with reference to FIG. 1.

The semiconductor structure 400 extends in a vertical direction (e.g., above a substrate) and has a length extending in the y-direction (e.g., into the page of FIG. 4A). Fabrication of semiconductor structure 400 may include performing a lithography and/or etching process to pattern a substrate, and/or to pattern a layer formed on the substrate (e.g., pattern an epitaxially grown SiGe layer over a substrate such as a silicon substrate). In an embodiment, the semiconductor structure 400 may be formed according to aspects of FIGS. 3A-3O.

The semiconductor structure 400 includes a first portion of germanium comprising material 402, and an upper portion overlying the germanium comprising material 402. In an embodiment, the germanium comprising portion 402 is silicon germanium. The portion 402 may be formed using the blocks 102 and/or 104 of the method 100 of FIG. 1, discussed above. In other embodiments, the portion 402 is formed by etching a silicon germanium substrate to form the fin structure and/or etching a layer of silicon germanium grown on the substrate to form the fin structure.

In an embodiment, the upper portion 404 of the semiconductor structure 400 is a first semiconductor composition, such as silicon, while the fin structure 402 is another semiconductor composition such as SiGe. In an embodiment, the upper portion 404 comprises a crystalline silicon (c-Si). As illustrated in FIG. 2A, the upper portion 404 may completely cover a top surface of the fin structure 402. The upper portion 404 may be formed using one or more aspects of the block 106 of the method 100 of FIG. 1.

In an embodiment, the upper portion 404 has a width W3 and a height H3. In an embodiment, width W3 is between approximately 0.1 nanometers (nm) and approximately 20 nm. In an embodiment, height H3 is between approximately 0.1 and approximately 10.0 nm. In an embodiment, the upper portion 404 has a curved or curvilinear upper surface. An angle θ2 is an angle of material of the upper portion 404 (e.g., c-Si) extending above the fin structure 404 (e.g., SiGe). In some implementations, the angle θ2 is between approximately 0<θ≤120º.

In an embodiment, the semiconductor structure 400 provides for an active region of a transistor device such as a fin-type field effect transistor (FinFET). In an embodiment, the upper portion 404 (e.g., c-Si) and the fin portion 402 (e.g., SiGe) include portions of a channel region of a FinFET device. FIG. 4B is illustrative of a perspective view of such a FinFET device, a device 406 where a gate structure 210 disposed over the structure 400, and source/drain regions 212 are disposed on each side of the gate structure 210 to form the device 406. The gate structure 210 includes a gate dielectric layer 210A and an overlying gate electrode layer 210B, which may be substantially similar to as discussed above with reference to FIG. 2C. Spacer elements 214 abut the sidewalls of the gate structure 210; and isolation features 216 interpose the fins 204. These features may also be substantially similar to as discussed above with reference to FIG. 2C.

It is noted that the semiconductor structure 400 in its channel region, under the gate 210, may be configured substantially similar to as illustrated in FIG. 4A. In some implementations, a gate dielectric layer, for example, an interfacial layer may be formed directly on the semiconductor structure 400 including on the surface of the upper portion 404. The FinFET device 406 including the structure 400 may be formed using aspects of the method 100 of FIG. 1, including for example block 104 (e.g., forming a germanium comprising layer 402) and block 106 (e.g., forming a crystalline silicon layer as upper portion 404).

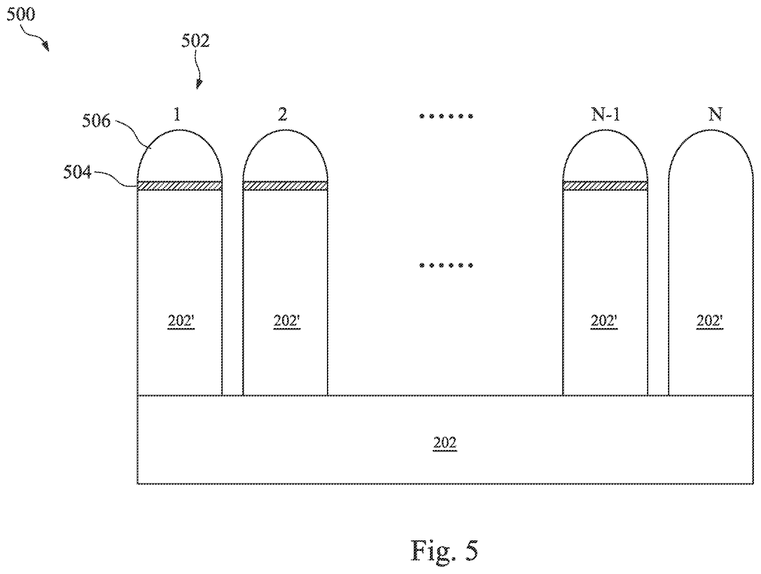

FIG. 5 is another embodiment of fabricating a semiconductor structure 500. The semiconductor structure of FIG. 5 may also be fabricated using one or more features of the method 100 discussed above with reference to FIG. 1. The semiconductor structure 500 includes a plurality of fin structures 502 extending above a substrate 202. The substrate 202 may be substantially similar to as discussed above. In an embodiment, a first set of the plurality of fin structures 502 include a first portion 202′, a germanium comprising layer 504, and an upper portion 506. In an embodiment, the first portion 202′ is silicon. In some implementations, the first portion 202′ is substantially similar to fins 204 discussed above with reference to FIGS. 2A, 2B, and 2C. In some implementations, the first portion 202′ is substantially similar to the mesa 202′ discussed above with reference to FIGS. 3F, 3K, 3L, 3M, 3N, and 3O.

In an embodiment, the germanium comprising layer 504 is germanium. In some implementations, the germanium comprising layer 504 is silicon germanium. In some implementations, the germanium comprising layer 504 is substantially similar to the germanium comprising layer 206 discussed above with reference to FIGS. 2A, 2B, and 2C. In some implementations, the germanium comprising layer 504 is substantially similar to the germanium comprising layer 306 discussed above with reference to FIGS. 3D-3O. The germanium comprising layer 504 may be formed by deposition and/or diffusion.

In an embodiment, the upper portion 506 is crystalline silicon (c-Si). In some implementations, the upper portion 506 is substantially similar to the portion 208 discussed above with reference to FIGS. 2A, 2B, and 2C. In some implementations, the upper portion 506 is substantially similar to the upper portion 308 discussed above with reference to FIGS. 3D-3O. The upper portion 506 may be fabricated substantially similar to as discussed above with reference to block 106 of the method 100 of FIG. 1.

The structure 500 is illustrative of an implementation of a multi-fin semiconductor device with a fin number of N (e.g., quantity of fins “N”), where N is greater than 0. In an embodiment, N is a number of silicon fins disposed on the substrate. In an embodiment, N is a number of silicon fins providing a silicon channel for a transistor device. The structure 500 illustrates the number of fin structures having a germanium comprising layer 504 in said fins may be n, where n is greater than or equal to 0. In an embodiment, N≥n≥0. In other words, in some implementations, one or more fins may be silicon fins and may omit a germanium-comprising layer, while one or more fins are silicon fins and include a germanium-comprising layer.

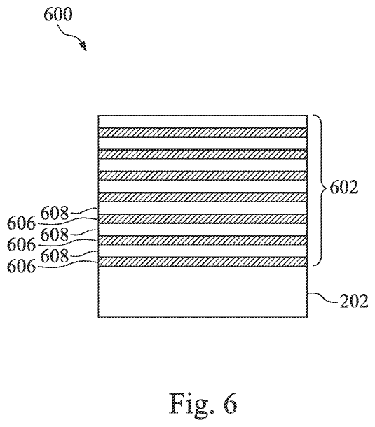

In another embodiment of forming a transistor device using aspects of the method 100 of FIG. 1, a multigate transistor in a gate-all-around (GAA) configuration is formed. The GAA configuration may include forming a semiconductor structure to provide a channel region, where the semiconductor structure is formed using one or more aspects of the method 100 of FIG. 1. In forming the GAA device, the semiconductor structure is processed to provide a nanobar or nanosheet, referred to generally as a nanostructure, to provide a channel region. FIGS. 6, 7, 8, 9, 10, 11A, 12 and 13 are illustrative of processing steps in forming a GAA device 600.

Referring to example of FIG. 6, illustrated is a semiconductor structure having a substrate 202 and a stack of layers 602 formed thereover. In an embodiment, substrate 202 includes silicon. Substrate 202 may alternatively or additionally include another elementary semiconductor, such as germanium; a compound semiconductor, such as silicon carbide, gallium arsenide, gallium phosphide, indium phosphide, indium arsenide, indium antimonide, or a combination thereof; an alloy semiconductor, such as SiGe, GaAsP. AlInAs, AlGaAs, GaInAs, GaInP. GaInAsP, or a combination thereof; or a combination thereof. In some embodiments, substrate 202 is a semiconductor-on-insulator substrate, such as a silicon-on-insulator substrate, a silicon germanium-on-insulator substrate, or a germanium-on-insulator substrate. Substrate 202 may include various doped regions, such as p-type doped regions/p-wells in n-type transistor regions and n-type doped regions/n-wells in p-type transistor regions. The n-wells are doped with n-type dopants, such as phosphorus, arsenic, other n-type dopant, or a combination thereof. The p-wells are doped with p-type dopants, such as boron, indium, other p-type dopant, or a combination thereof. In some embodiments, substrate 202 includes doped regions formed with a combination of p-type dopants and n-type dopants. The various doped regions may be formed directly on and/or in substrate 202, for example, providing a p-well structure, an n-well structure, a dual-well structure, a raised structure, or a combination thereof. An ion implantation process, a diffusion process, and/or other suitable doping process may be performed to form the various doped regions.

A stack of semiconductor layers 602 is formed over the substrate 202. The stack 602 includes semiconductor layer 606 and semiconductor layer 608. Semiconductor layers 606 and semiconductor layers 608 are stacked vertically (e.g., along the z-direction) in an interleaving or alternating configuration from a top surface of substrate 202. A composition of semiconductor layers 606 and a composition of semiconductor layers 608 are different to achieve etching selectivity and/or different oxidation rates during processing. For example, semiconductor layers 606 and semiconductor layers 608 include different materials, constituent atomic percentages, constituent weight percentages, thicknesses, other characteristics, or a combination thereof to achieve desired etching selectivity. The semiconductor layers 608 may be referred to as channel regions, as they are processed to form the channel region of the device 600. The semiconductor layers 606 may be referred to as interposer, or sacrificial layers, as they are subsequently removed to provide an opening within which a gate is formed. In an embodiment, semiconductor layers 608 include silicon and semiconductor layers 606 include silicon germanium having a germanium atomic percent greater than zero. In an embodiment, semiconductor layers 608 include silicon germanium with a first germanium atomic percent, semiconductor layers 606 include silicon germanium having a second germanium atomic percent. With such compositions, semiconductor layers 606 may have a first etch rate to an etchant and semiconductor layers 608 may have a second etch rate to the etchant, where the first etch rate and the second etch rate are different. In some embodiments, forming the semiconductor layer stack 602 includes epitaxially growing semiconductor layers 606 and semiconductor layers 608 in the depicted interleaving and alternating configuration over substrate 202. Epitaxial growth is achieved by a molecular beam epitaxy (MBE) process, a chemical vapor deposition (CVD) process, a metalorganic chemical vapor deposition (MOCVD) process, other suitable epitaxial growth process, or a combination thereof.

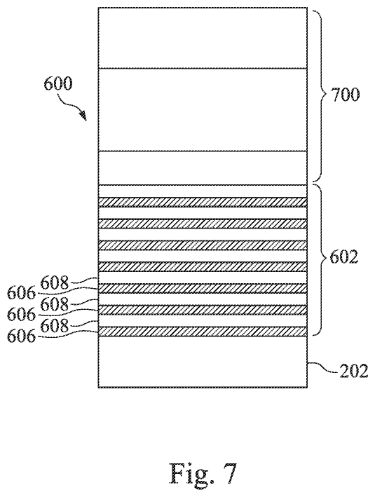

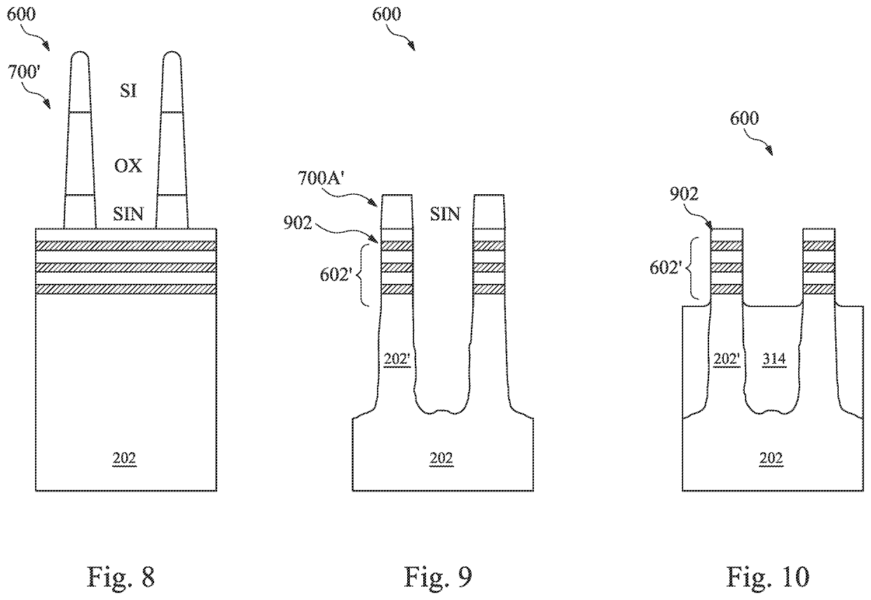

As illustrated in FIG. 7, a hard mask layer 700 is formed over the stack 602. The hard mask layer 700 may include multiple layers such as 700A (e.g., oxide), 700B, (e.g., nitride), 700C (e.g., silicon such as amorphous Si). The hard mask layer 700 is used in a fin fabrication process to form fins of the stack 602 and/or the substrate 202. The hard mask layer 700 is etched to define areas within which the fin elements are to be formed such as illustrated in FIG. 8.

Referring to FIG. 9, a fin fabrication process is performed to form fins 902 extending from a substrate (wafer) 202. Fins 902 extend substantially parallel to one another along an x-direction, having a length in the x-direction (into the page of FIG. 9), a width in a y-direction (along the page of FIG. 9), and a height in a z-direction. Each of fins 902 include a substrate portion 202′ and a semiconductor layer stack portion 602′ disposed over the substrate 202′ portion.

The semiconductor layers 608 or portions thereof form channel regions of transistors in multigate device. In the depicted embodiment, each semiconductor layer stack 602 includes seven semiconductor layers 608. However, the present disclosure contemplates embodiments where semiconductor layer stack 602 includes more or less semiconductor layers, for example, depending on a number of channels desired for multigate device and/or design requirements of multigate device.

Formation of fins 902 may include performing a lithography and/or etching process to pattern the semiconductor layer stack 602 and/or substrate 202. The lithography process may include forming a resist layer over the semiconductor layer stack 602 and hard mask 700 (for example, by spin coating), performing a pre-exposure baking process, performing an exposure process using a mask, performing a post-exposure baking process, and performing a developing process. After development, the patterned resist layer includes a resist pattern that corresponds with the mask. The etching process removes portions of the semiconductor layer stack precursor and/or substrate 202 using the patterned resist layer and the patterned hard mask layer 700′ (FIG. 8) as an etch mask. The etching process is a dry etch, a wet etch, other suitable etching process, or a combination thereof. In some embodiments, the etching process is a reactive ion etching (RIE) process. After etching, the patterned resist layer and/or the hard mask layer 700A′ may be removed, for example, by a resist stripping process or other suitable process.

In some embodiments, fins 902 are formed by a multiple patterning process, such as a double patterning lithography (DPL) process (for example, a lithography-etch-lithography-etch (LELE) process, a self-aligned double patterning (SADP) process, a spacer-is-dielectric (SID) SADP process, other double patterning process, or a combination thereof), a triple patterning process (for example, a lithography-etch-lithography-etch-lithography-etch (LELELE) process, a self-aligned triple patterning (SATP) process, other triple patterning process, or a combination thereof), other multiple patterning process (for example, a self-aligned quadruple patterning (SAQP) process), or a combination thereof.

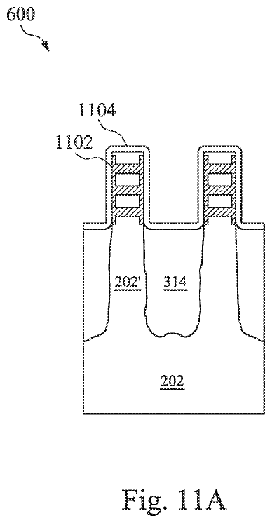

In etching the fins 902, trenches are between fins 902 as illustrated in FIG. 9. The trenches are filled with isolation material to form isolation features 314 extending between fins 902 as illustrated in FIG. 10. Isolation features 314 fill lower portions of trenches and surround portions of fins 902. Portions of fins 902 that extend from top surfaces of isolation features 314 may be referred to as fin active regions. Isolation features 314 electrically isolate active device regions and/or passive device regions. For example, isolation features 314 separate and electrically isolate fins 902 from each other and/or from other device regions/features. Isolation features 314 include silicon oxide, silicon nitride, silicon oxynitride, other suitable isolation material (for example, including silicon, oxygen, nitrogen, carbon, etc.), or a combination thereof. Isolation features 314 may have a multilayer structure. For example, isolation features 314 include a bulk dielectric (e.g., an oxide layer) over a dielectric liner (for example, silicon nitride, silicon oxide, silicon oxynitride, silicon oxycarbonitride, or a combination thereof). In another example, isolation features 314 include a bulk dielectric over a doped liner, such as a boron silicate glass (BSG) liner and/or a phosphosilicate glass (PSG) liner. Dimensions and/or characteristics of isolation features 314 are configured to provide shallow trench isolation (STI) structures, deep trench isolation (DTI) structures, local oxidation of silicon (LOCOS) structures, other suitable isolation structures, or a combination thereof. After depositing insulating materials, the materials recessed and/or etched back, such that fins 902 protrude from isolation features 314.

After etching back the isolation features 314, the fin 902 is provided with exposed sidewalls and top surfaces. In some implementations, fabrication of the device 600 implements features of the method 100 of FIG. 1 discussed above. That is, in some implementations, this structure having fins 902 extending from the substrate 202 provides a semiconductor structure as provided in block 102 of the method 100 of FIG. 1. Again, when etched, the semiconductor layers 608, which form the channel of the GAA formed, may be referred to as nanosheets or nanobars or generally nanostructures, which may include channel regions of various geometries and dimensions.

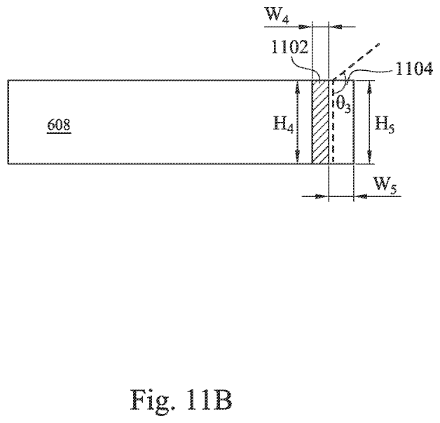

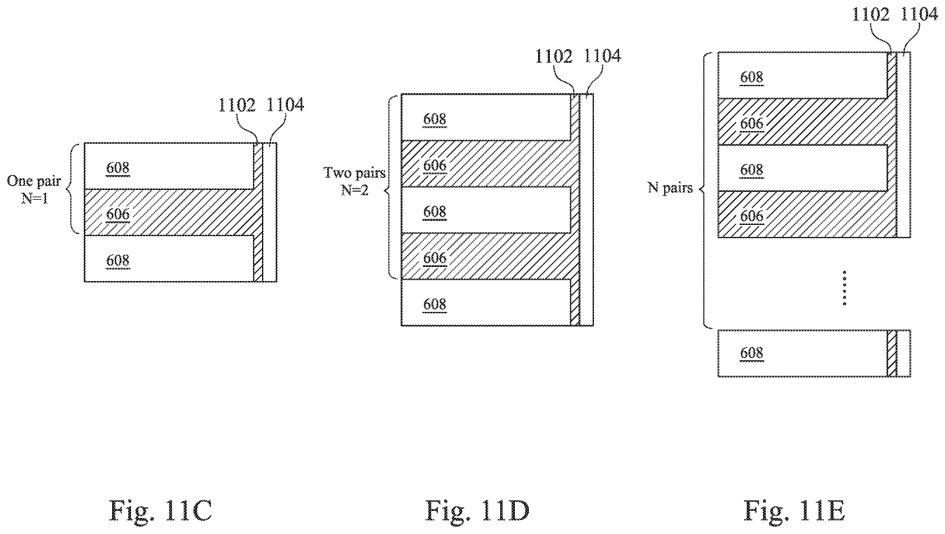

A germanium-comprising layer is formed on the exposed sidewalls and top surfaces of the fin 902. Providing a germanium-comprising layer on the semiconductor structure may be substantially similar to block 104 of the method 100 of FIG. 1, discussed above. Referring to the example of FIG. 11A, a germanium-comprising layer 1102 is provided on the sidewalls of the fin 902. In an embodiment, the germanium-comprising layer 1102 is formed on a top surface of the fin 902. In other embodiments, the germanium-comprising layer 1102 is formed on the sidewalls of the fin 902 and does not extend to a top surface. In an embodiment, the germanium-comprising layer 1102 is germanium. In an embodiment, the germanium-comprising layer 1102 is silicon germanium. In some implementations, the germanium-comprising layer 1102 may be substantially similar to the germanium-comprising layer 206. In some implementations, the germanium-comprising layer 1102 may be substantially similar to the germanium-comprising layer 306. The germanium-comprising layer 1102 may be formed by deposition process. In an embodiment, the germanium-comprising layer 1102 may be formed by diffusion of germanium (e.g., from the layers 608 and/or 606) towards the amorphous silicon layer 1104 during its formation as discussed below.

A crystalline silicon (c-Si) is then formed on the sidewalls and top surfaces of the fin 902 and over the germanium-comprising layer 1102. Providing a crystalline silicon layer may be performed substantially similar to block 106 of the method of FIG. 1, discussed above. Referring to the example of FIG. 11A, a crystalline silicon layer 1104 is provided on the sidewalls of the fin 902. In an embodiment, the crystalline silicon layer 1104 is formed on a top surface of the fin 902. In an embodiment, the crystalline silicon layer 1104 may be formed directly on the germanium-comprising layer 1102. In an embodiment, an interface between the crystalline silicon layer 1104 and the germanium-comprising layer 1102 develops as the germanium diffuses to the germanium-comprising layer 1102 during the formation of the c-Si layer 1104. In some implementations, the formed crystalline silicon layer 1104 may be substantially similar to the crystalline silicon portion 208. In some implementations, the crystalline silicon layer 1104 may be substantially similar to the crystalline silicon layer 308. In some implementations, an upper surface of the crystalline silicon layer 1104 may be substantially planar. In some implementations, an upper surface of the crystalline silicon layer 1104 may be substantially parallel a top surface of the stack 602.

In an embodiment, the germanium-comprising layer 1102 and the crystalline silicon layer 1104 are formed on an uppermost layer of the stack 602 being a semiconductor layer 608, where the semiconductor layer 608 is silicon. In an embodiment, the germanium-comprising layer 1102 and the crystalline silicon layer 1104 is formed on a semiconductor layer 608, where the semiconductor layer 608 is silicon germanium. In an embodiment, the semiconductor layer 608 is a Si1−xGe composition where x is between 0%≤X<30%.

FIG. 11B illustrates exemplary dimensions of the germanium-comprising layer 1102 and the crystalline silicon layer 1104 formed on the semiconductor layer 608 (e.g., a nanostructure channel layer). The germanium-comprising layer 1102 has a width W4. The germanium-comprising layer 1102 has a thickness H4. In an embodiment, W4 is between approximately 0.1 nm and approximately 20.0 nm. In an embodiment, H4 is between approximately 0.1 nm and approximately 20.0 nm.

The crystalline silicon layer 1104 has a width W5. The crystalline silicon layer 1104 has a thickness H5. In an embodiment, W5 is between approximately 0.1 nm and approximately 20.0 nm. In an embodiment, H5 is between approximately 0.1 nm and approximately 20.0 nm. In an embodiment, a contact angle θ3 of the crystalline silicon layer 1104 and the germanium-comprising layer 1102 is between approximately 0<0<1200. In an embodiment, the nanostructure layer 608 is silicon germanium. In a further embodiment, the nanosheet 608 is a Si₁₋ₓGeₓ composition, where 0%≤x<30%. In some implementations, germanium from this layer 608 diffuses to form the germanium-comprising layer 1102 having a greater germanium concentration than the layer 608.

FIGS. 11C, 11D, and 11E illustrate portions of a fin structure 902 in various embodiments. In FIG. 11C, one pair of semiconductor layers 606/608 is illustrated. In FIG. 11D, two pairs of semiconductor layers 606/608 are illustrated. In FIG. 11E, N pairs of semiconductor layers 606/608 are provided, where N is greater than zero. In some implementations, the number of germanium-comprising layers 1102 on the semiconductor layer 608 (e.g., Si) is N≥n≥0. Each of these configurations may form a stack such as the stack 602. In some implementations, the semiconductor layers 606 and 608 each include silicon germanium, where at least the semiconductor layer 608 includes Si₁₋ₓGeₓ composition, where 0%≤x<30%. In an embodiment, the semiconductor layer 606 includes stoichiometric SiGe. In some implementations, the germanium comprising layer 1102 is formed by diffusion of germanium from the layers 608/606 during the formation of the c-Si layer 1104 including as discussed above.

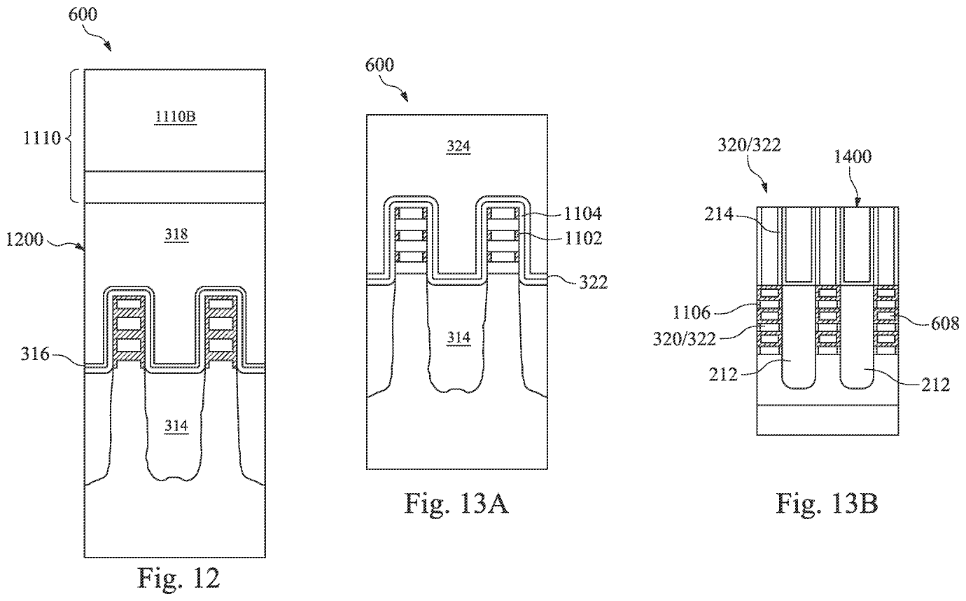

Turning to FIG. 12, after etching the fins 902, a dummy gate stack 1200 is formed over the fins 902. Dummy gate 1200 extends lengthwise in a direction that is different than (e.g., orthogonal to) the lengthwise direction of fins 902. For example, dummy gate stack 1200 extends along the y-direction, having a length in the y-direction, a width in the x-direction, and a height in the z-direction. Dummy gate stack 1200 includes a dummy gate dielectric 316, a dummy gate electrode 318, and a hard mask 1110 (including, for example, a first mask layer 1100A and a second mask layer 1100B). In an embodiment, the hard mask layer 1100A includes a silicon nitride layer. Exemplary thicknesses of the hard mask layer 1100A include 1000 Angstroms to 1500 Angstroms. In an embodiment, the hard mask layer 1100B includes an oxide layer such as silicon oxide. As exemplary thickness of the hard mask layer 1100B may be greater than 2000 Angstroms. Dummy gate dielectric 316 includes a dielectric material, such as silicon oxide, a high-k dielectric material, other suitable dielectric material, or a combination thereof. For example, in an embodiment, the dummy gate dielectric 316 is an oxide layer. Dummy gate electrode 318 includes a suitable dummy gate material, such as polysilicon. In some embodiments, dummy gate stack includes other layers, such as a capping layer, an interface layer, a diffusion layer, a barrier layer, or a combination thereof. Dummy gate stack 316/318 is formed by deposition processes, lithography processes, etching processes, other suitable processes, or a combination thereof.

After forming the dummy gate stack 316/318 over a channel region of the fin 902, source/drain features may be formed adjacent the dummy gate stack 316/318. In some implementations, at least one gate spacer layer 214 is over the sidewalls of the dummy gate stack 316/318 before the source/drain regions are recessed. The etch process may be a dry etch process or a suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. After the recess, inner spacers 1106 may be formed on sidewalls of sacrificial semiconductor layers 206. In an example processes to form the gate stack spacers 214 and/or inner spacers 1106, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After deposition, the spacer material is etched back. In other implementations, inner spacer features 1106 are formed by oxidizing portions of the sacrificial semiconductor layer 206 (e.g., forming SiGeOx).

Source/drain features 212 may be formed using an epitaxial process, such as VPE, UHV-CVD, MBE, and/or other suitable processes to fill the recesses in the fin 902. The epitaxial growth process may use gaseous and/or liquid precursors, which interact with the composition of the semiconductor layers 608 and/or substrate 202. In some implementations, the source/drain feature is a p-type source/drain feature and may include silicon germanium (SiGe) doped with a p-type dopant, such as boron (B) and some implementations the source/drain feature is an n-type source/drain feature and may include silicon (Si) doped with phosphorus (P). The source/drain features may be substantially similar to the source/drain features 212, discussed above with respect to FIGS. 2C and 4B.

After formation of the source/drain features, a dielectric layer comprising a contact etch stop layer (CESL) and/or an interlayer dielectric (ILD) layer are deposited. The CESL may include silicon nitride, silicon oxynitride, and/or other materials known in the art and may be formed by CVD, ALD, plasma-enhanced chemical vapor deposition (PECVD) process and/or other suitable deposition or oxidation processes. The ILD layer is deposited over the CESL by spin-on coating. FCVD. CVD, or other suitable deposition technique. The ILD layer may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The dielectric layer is illustrated as dielectric layer 1400 in the perspective view of the device 600 in FIG. 14.

The dummy gate stack 316/318 is then removed from the substrate 202 and the channel layers, semiconductor layers 608, are released by removing the sacrificial semiconductor layers 606. In some implementations, the germanium-comprising layer 1102 and/or the c-Si layer 1104 may be removed during the removal of the dummy gate and/or the channel release process. In some implementations, the removal of the dummy gate and/or the channel release may be selective to the c-Si 1104 and/or germanium comprising layer 1102 such that the layer(s) are maintained in the device 600.

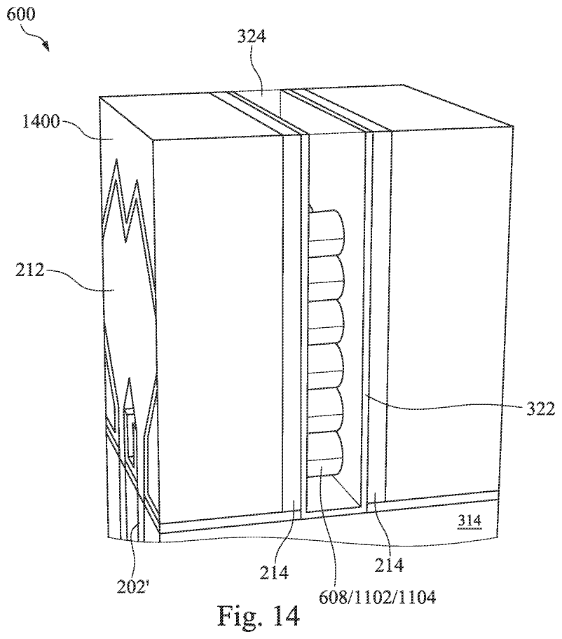

A metal gate structure may then be formed on and surrounding the semiconductor layers 608, the gate structure including a gate dielectric 322 and a metal gate 324 formed over the gate dielectric 322 as illustrated in FIGS. 13A, 13B. In some implementations, the gate dielectric 322 may be formed directly on the crystalline silicon layer 1104 (if present). In various embodiments, the gate dielectric 322 includes an interfacial layer (IL) and a high-K gate dielectric layer formed over the interfacial layer. High-K gate dielectrics, as used and described herein, include dielectric materials having a high dielectric constant, for example, greater than that of thermal silicon oxide (˜3.9) as discussed above. In various embodiments, the gate electrode 324 includes a conductive layer such as W, Ti, TIN, TiAl, TiAlN, Ta, TaN, WN, Re, Ir, Ru, Mo, Al, Cu, Co, CoSi, Ni, NiSi, combinations thereof, and/or other suitable compositions. The gate electrode 324 may include work function metals tuned for the device performance. In some embodiments, the gate electrode 324 may alternately or additionally include a polysilicon layer. In various examples, the gate electrode 324 may be formed using PVD, CVD, electron beam (e-beam) evaporation, and/or other suitable process.

FIG. 13A illustrates the metal gate electrode 324 and high-k gate dielectric 322 formed around the channel regions 608. In some implementations, a portion of the germanium-comprising layer 1102 remains on the channel layers 608. In an embodiment, a portion of the c-Si layer 1104 remains on the germanium-comprising layer 1102.

FIG. 13B illustrates a cross-sectional view along the fin 902 which shows that in an embodiment, a germanium comprising layer 1102 remains encircling the channel layer 608 with the metal gate electrode 324. The illustrated embodiment may include the germanium comprising layer 1102 on the upper surface of the channel layers 608 (e.g., due to diffusion or deposition of the germanium comprising layer 1102 or due to residue from the sacrificial layer 606). In other embodiments, the germanium comprising layer 1102 is not found on the upper surface of the channel layers 608 but may be present on the sidewalls of the channel layers 608.

FIG. 14 illustrates an exemplary perspective view of the device 600. Insulation 1400 may include a contact etch stop layer and/or an interlayer dielectric layer and be disposed over the isolation features 314 and the source/drain regions 212. The CESL may include silicon nitride, silicon oxynitride, and/or other materials known in the art and may be formed by CVD, ALD, plasma-enhanced chemical vapor deposition (PECVD) process and/or other suitable deposition or oxidation processes. The ILD layer is deposited over the CESL by spin-on coating, FCVD, CVD, or other suitable deposition technique. The ILD layer may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

The illustrative devices including the device 220 (e.g., FinFET device), the device of FIG. 3N, the device 406, the device 500, and the device 600 may be a device of an integrated circuit device where the device is disposed in a core region (often referred to as a logic region), a memory region (such as a static random access memory (SRAM) region), an analog region, a peripheral region (often referred to as an input/output (I/O) region), a dummy region, other suitable region, or a combination thereof. Other components formed on the substrate can include various passive and active electronic devices, such as resistors, capacitors, inductors, diodes, p-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable devices, or a combination thereof to form a microprocessor, a memory, other IC device, or a combination thereof.

From the foregoing description, it can be seen that multigate devices described in the present disclosure offer advantages over conventional multigate devices. It is understood, however, that other embodiments may offer additional advantages, and not all advantages are necessarily disclosed herein, and that no particular advantage is required for all embodiments. One advantage of the fabrication processes described herein in some implementations is the crystalline silicon layer provides for protection of a fin structure during fabrication of a device including protection from or mitigation of undesired oxidation or damage to the fin structure in the channel region.

The present disclosure provides for many different embodiments. An exemplary method of fabricating a semiconductor device includes forming a channel region of the semiconductor device. Forming the channel region includes providing a germanium-comprising layer; and depositing a crystalline silicon layer on the germanium-comprising layer. The method includes forming a gate structure over a first surface and a second surface, the second surface opposing the first surface.

In a further embodiment, providing the germanium-comprising layer includes forming a germanium layer over a silicon fin including at least one of deposition of the germanium layer or diffusion of germanium to form the germanium layer. In an embodiment, providing the germanium-comprising layer includes depositing a germanium layer over a silicon germanium nanostructure having diffusion of germanium to form the germanium layer. In an embodiment, providing the germanium-comprising layer includes forming a fin structure having a first portion comprising silicon and the germanium-comprising layer over the first portion. The germanium-comprising layer may include forming silicon germanium on the first portion comprising silicon. In some implementations, providing the germanium-comprising layer includes: providing a silicon substrate; etching a recess in the silicon substrate; growing the germanium-comprising layer in the recess; and etching a fin structure including a portion of the silicon substrate and the germanium-comprising layer. And in an embodiment, at least one of the first surface and the second surface is the crystalline silicon layer.

In another of the broader embodiments, a method is provided that includes forming a trench in a silicon substrate and forming a germanium comprising layer on the silicon substrate including in the trench. A crystalline silicon material is deposited over the germanium layer. The crystalline silicon material, silicon germanium comprising layer, and the silicon substrate are patterned to form a fin structure. The fin structure includes a lower portion comprising the silicon substrate, a middle portion comprising the germanium comprising layer, and an upper portion comprising the crystalline silicon material. A gate structure is formed extending over the fin structure.

In an embodiment, forming the gate structure includes depositing a gate dielectric layer interfacing an upper surface of the upper portion comprising the crystalline silicon material, which may further include depositing a gate dielectric layer interfacing a sidewall of the germanium comprising layer. In an embodiment, the crystalline silicon material and a second region of the silicon substrate are patterned to form another fin structure. The crystalline silicon material may be disposed directly on the second region of the silicon substrate. In some implementations the gate structure is formed extending over the fin structure and over another fin structure. In an embodiment, the crystalline silicon material includes introducing a precursor of at least one of silane (SiH₄) or disilane (Si₂H₆).

In an embodiment of the method, the method includes forming another recess in the fin structure adjacent the gate structure; and growing an epitaxial source/drain feature in the another recess. In some implementations of the method, patterning the crystalline silicon material, germanium comprising layer, and the silicon substrate to form the fin structure includes forming a hard mask layer directly on the crystalline silicon material; patterning the hard mask layer; and using the patterned hard mask layer as a masking element when patterning the crystalline silicon material, germanium comprising layer, and the silicon substrate.

In another of the broader embodiments discussed herein provided is a semiconductor device. The device includes a silicon substrate, a first channel region disposed over the silicon substrate, a germanium comprising layer on the first semiconductor material, a crystalline silicon layer on the germanium comprising layer; and a gate structure on at least two surfaces of the first channel region. The first channel region includes a first semiconductor material. In an embodiment, the first semiconductor material of the first channel region is a silicon nanostructure. In an embodiment, the first semiconductor material of the first channel region is a fin structure extending from the silicon substrate. In another implementation, the germanium comprising layer is a germanium layer disposed directly on a sidewall of the first semiconductor material. And in some implementations, one surface of the at least two surfaces of the first channel region is a curvilinear upper surface of the crystalline silicon layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device comprising:
forming a channel region of the semiconductor device, wherein forming the channel region includes:
providing a germanium-comprising layer; and
depositing a crystalline silicon layer on the germanium-comprising layer; and
forming a gate structure over a first surface and a second surface, the second surface opposing the first surface.

2. The method of claim 1, wherein the providing the germanium-comprising layer includes forming a germanium layer over a silicon fin, wherein the forming includes at least one of deposition of the germanium layer or diffusion of germanium to form the germanium layer.

3. The method of claim 1, wherein the providing the germanium-comprising layer includes depositing a germanium layer over a silicon germanium nanostructure, wherein the forming includes diffusion of germanium to form the germanium layer.

4. The method of claim 1, wherein the providing the germanium-comprising layer includes forming a fin structure having a first portion comprising silicon and the germanium-comprising layer over the first portion.

5. The method of claim 4, wherein the germanium-comprising layer includes forming silicon germanium on the first portion comprising silicon.

6. The method of claim 1, wherein the providing the germanium-comprising layer includes:
providing a silicon substrate;
etching a recess in the silicon substrate;
growing the germanium-comprising layer in the recess; and
etching a fin structure including a portion of the silicon substrate and the germanium-comprising layer.

7. The method of claim 1, wherein at least one of the first surface and the second surface is the crystalline silicon layer.

8. A method, comprising:
forming a trench in a silicon substrate;
forming a germanium comprising layer on the silicon substrate including in the trench;
depositing a crystalline silicon material over the germanium comprising layer;
patterning the crystalline silicon material, silicon germanium comprising layer, and the silicon substrate to form a fin structure, wherein the fin structure includes a lower portion comprising the silicon substrate, a middle portion comprising the germanium comprising layer, and an upper portion comprising the crystalline silicon material; and
forming a gate structure extending over the fin structure.

9. The method of claim 8, wherein the forming the gate structure includes:
depositing a gate dielectric layer interfacing an upper surface of the upper portion comprising the crystalline silicon material.

10. The method of claim 9, wherein the forming the gate structure includes:
depositing a gate dielectric layer interfacing a sidewall of the germanium comprising layer.

11. The method of claim 8, further comprising:
patterning the crystalline silicon material and a second region of the silicon substrate to form another fin structure, wherein the crystalline silicon material is disposed directly on the second region of the silicon substrate.

12. The method of claim 11, wherein the forming the gate structure extending over the fin structure includes forming the gate structure over the another fin structure.

13. The method of claim 8, wherein the depositing the crystalline silicon material includes introducing a precursor of at least one of silane (SiH₄) or disilane (Si₂H₆).

14. The method of claim 8, further comprising:
forming another recess in the fin structure adjacent the gate structure; and
growing an epitaxial source/drain feature in the another recess.

15. The method of claim 8, wherein the patterning the crystalline silicon material, germanium comprising layer, and the silicon substrate to form the fin structure includes:
forming a hard mask layer directly on the crystalline silicon material;
patterning the hard mask layer; and
using the patterned hard mask layer as a masking element when patterning the crystalline silicon material, germanium comprising layer, and the silicon substrate.

16. A semiconductor device, comprising:
a silicon substrate;
a first channel region disposed over the silicon substrate, wherein the first channel region includes a first semiconductor material, a germanium comprising layer on the first semiconductor material, and a crystalline silicon layer on the germanium comprising layer; and
a gate structure on at least two surfaces of the first channel region.

17. The semiconductor device of claim 16, wherein the first semiconductor material of the first channel region is a silicon nanostructure.

18. The semiconductor device of claim 16, wherein the first semiconductor material of the first channel region is a fin structure extending from the silicon substrate.

19. The semiconductor device of claim 16, wherein the germanium comprising layer is a germanium layer disposed directly on a sidewall of the first semiconductor material.

20. The semiconductor device of claim 16, wherein one surface of the at least two surfaces of the first channel region is a curvilinear upper surface of the crystalline silicon layer.
